(19) United States
(12) Patent Application Publication
(10) Pub. No.: US 2026/0213717 A1
(43) Pub. Date: Jul. 23, 2026

(54) CONVERGED 2G AND 5G RF FRONT END MODULE WITH MULTI-MODE BALUN

(71) Applicant: SKYWORKS SOLUTIONS, INC., Irvine, CA (US)

(72) Inventors: Kun Chen, Thousand Oaks, CA (US); Yu-Jui Lin, Westlake Village, CA (US)

(21) Appl. No.: 19/448,205

(22) Filed: Jan. 14, 2026

Related U.S. Application Data
(60) Provisional application No. 63/747,945, filed on Jan. 22, 2025.

(51) Int. Cl. H03F 3/24; H03F 1/56

(52) U.S. Cl. CPC H03F 3/245; H03F 1/565; H03F 2200/171; H03F 2200/387; H03F 2200/451

(57) ABSTRACT

A radio frequency front-end module comprising: a module substrate; a semiconductor die attached to the module substrate, the semiconductor die including a power amplifier system formed on the semiconductor die and configured to amplify a radio frequency signal input to the radio frequency front-end module; an output matching network comprising a multi-mode balun formed on the module substrate, the multi-mode balun configured to tune the radio frequency signal to at least a first output mode having a first output power level in a first output frequency range and a second output mode having a second output power level in a second output frequency range, the multi-mode balun having an input side coupled to the power amplifier system and an output side including a plurality of output terminals directing the radio frequency signal from the power amplifier to the at least first and second output modes.

### CROSS-REFERENCE TO RELATED APPLICATIONS

This application claims priority under 35 U.S.C. § 119(e) to U.S. Provisional Application 63/747,945, titled CONVERGED 2G AND 5G RF FRONT END MODULE WITH MULTI-MODE BALUN, filed on January 22, 2025, which is hereby incorporated by reference in its entirety for all purposes.

### BACKGROUND

### Field

Aspect and embodiments of the present disclosure relate to a radio frequency front-end module that is capable of operating both 2G-mode and 5G-mode communications.

### Description of the Related Technology

As wireless communications systems evolve, more and more bands and functionalities are integrated into a single radio frequency (RF) front end module to minimize size, improve performance and save cost.

Entering the era of the Fifth Generation (5G) cellular communications, there is still a large population around the world relying on the Second Generation (2G) communications. There are frequency overlaps of 2G low band (LB), typically with frequency ranges of 824 MHz to 849 MHz and 880 MHz to 915 MHz, and 5G new radio low band (NR LB), typically with frequency ranges from 600 MHz to 1 GHz. This brings an opportunity to make a converged 2G + 5G solution for the RF front-end module, which leverages frequency overlaps.

However, the challenge lies in that 2G and 5G setups are normally of different power levels, and also have different linearity and harmonic specifications. To solve this problem, prior solutions include using two separate single ended power amplifiers which are a 2G power amplifier and a 5G push-pull power amplifier (also called a differential amplifier). However, the use of push-pull amplifiers poses challenges for the output match network (OMN) design to cover a wide frequency bands and at the same time, also to cover a wide power range.

Prior solutions also include using a single converged power amplifier realized by switchable capacitors with a single-mode balun, and adding switching termination capacitors to the balun. However, this solution has drawbacks of introducing additional switch losses associated with the switching termination capacitors.

Therefore, it is desirable to have a broadband switchable front end architecture to cover a wide range of frequency bands and wide power ranges for both 2G and 5G communications.

### SUMMARY

According to a first aspect there is provided a radio frequency front-end module comprising: a module substrate; a semiconductor die attached to the module substrate, the semiconductor die including a power amplifier system formed on the semiconductor die and configured to amplify a radio frequency signal input to the radio frequency front-end module; and an output matching network configured to tune the radio frequency signal to at least a first output mode having a first output power level in a first output frequency range and a second output mode having a second output power level in a second output frequency range, the output matching network including a multi-mode balun having an input side coupled to the power amplifier system and an output side having a plurality of output terminals directing the radio frequency signal from the power amplifier to the at least first and second output modes.

In one example, the input side of the multi-mode balun has a primary winding having a positive input terminal, a negative input terminal, and a center tap directed to ground.

In one example, the output side of the multi-mode balun has a secondary winding having a first output terminal directed to the first output mode of the multi-mode balun, a second output terminal directed to ground and at least one output tap directed to the second output mode of the multi-mode balun.

In one example, the power amplifier system further comprises a first input power amplifier, a first output power amplifier, a second output power amplifier and an input transformer.

In one example, an output of the first output power amplifier is coupled to the positive input terminal, and an output of the second output power amplifier is coupled to the negative input terminal.

In one example, the power amplifier system further comprises a first capacitor coupled at the output of the first output power amplifier, and a second capacitor coupled at the output of the second output power amplifier.

In one example, the power amplifier system further comprises a third switchable capacitor coupled at the output of the first output power amplifier, and a fourth switchable capacitor coupled at the output of the second output power amplifier.

In one example, the multi-mode balun is in a multi-layer structure including at least a top layer having a positive input terminal and a negative input terminal, a first middle layer having a first output terminal, a second middle layer having a center input tap, and a bottom layer having a plurality of output taps.

In one example, the top layer is connected to the second middle layer forming the input side of the multi-mode balun and the bottom layer is connected to the first middle layer forming the output side of the multi-mode balun.

In one example, the bottom layer is connected to the first middle layer forming the output side of the multi-mode balun.

In one example, the first output frequency range is within a Second Generation communication frequency range and the second output frequency range is within a Fifth Generation communication frequency range.

In one example, the first output frequency range is 824 MHz to 849 MHz or 880 MHz to 915 MHz.

In one example, the second output frequency range is 600 MHz to 1 GHz.

In one example, the multi-mode balun is configured to provide a third output mode having a third output power level in a third output frequency range.

In one example, the third output frequency range is within a Fifth Generation communication frequency range.

In one example, the output matching network further comprises a band filtering circuitry formed on the module substate and coupled to the multi-mode balun, the band filtering circuitry including a plurality of band filters.

In one example, the radio frequency front-end module further comprises a band switch formed on a silicon switch die attached to the module substrate and configured to switch between the first output mode and the second output mode.

According to a second aspect there is provided a mobile device comprising: a transceiver configured to generate a radio frequency input signal, and a radio frequency front-end module including: a module substrate; a semiconductor die attached to the module substrate, the semiconductor die having a power amplifier system formed on the semiconductor die and configured to amplify a radio frequency signal input to the radio frequency front-end module; and an output matching network configured to tune the radio frequency signal to at least a first output mode having a first output power level in a first output frequency range and a second output mode having a second output power level in a second output frequency range, the output matching network having a multi-mode balun having an input side coupled to the power amplifier system and an output side having a plurality of output terminals directing the radio frequency signal from the power amplifier to the at least first and second output modes.

In one example, the multi-mode balun is in a multi-layer structure including at least a top layer, a first middle layer, a second middle layer, and a bottom layer.

In one example, the first output frequency range is within a Second Generation communication frequency range and the second output frequency range is within a Fifth Generation communication frequency range.

In one example, the first output frequency range is 824 MHz to 849 MHz or 880 MHz to 915 MHz.

In one example, the second output frequency range is 600 MHz to 1 GHz.

According to a third aspect there is provided a method for processing a radio frequency signal, the method comprising: inputting a radio frequency to a radio frequency front-end module formed on a module substrate; amplifying the radio frequency signal using a power amplifier system formed on a semiconductor die attached to the module substrate; tuning the amplified radio frequency signal, using an output matching network, to at least a first output mode having a first output power level in a first output frequency range and a second output mode having a second output power level in a second output frequency range, including forming the at least first and second output modes using a multi-mode balun, the multi-mode balun having an input side coupled to the power amplifier system and an output side having a plurality of output terminals directing the radio frequency signal from the power amplifier to form the at least first and second output modes.

In one example, the multi-mode balun is in a multi-layer structure including at least a top layer, a first middle layer, a second middle layer, and a bottom layer.

In one example, the first output frequency range is within a Second Generation communication frequency range and the second output frequency range is within a Fifth Generation communication frequency range.

In one example, the first output frequency range is 824 MHz to 849 MHz or 880 MHz to 915 MHz.

In one example, the second output frequency range is 600 MHz to 1 GHz.

According to a fourth aspect there is provided a radio frequency circuit for wireless communication, the radio frequency circuit comprising: an output matching network configured to tune a radio frequency signal to at least a first output mode having a first output power level in a first output frequency range and a second output mode having a second output power level in a second output frequency range, the output matching network including a multi-mode balun having an input side configured to receive the radio frequency signal and an output side having a plurality of output terminals configured to tune the power levels of the radio frequency signal and direct the radio frequency signal to the at least first and second output modes.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic diagram of a radio frequency front-end module according to present disclosure;

FIG. 2 is a detailed schematic diagram of a radio frequency front-end module according to one example;

FIG. 3 is a detailed schematic diagram of a radio frequency front-end module according to another example;

FIG. 4 is a detailed schematic diagram of a radio frequency front-end module according to another example;

FIG. 5 is a detailed schematic diagram of a radio frequency front-end module according to another example;

FIG. 6 is a detailed schematic diagram of a radio frequency front-end module according to another example.

FIG. 7 is a schematic diagram of a multi-mode balun including at least a top layer, a first middle layer, a second middle layer and a bottom layer according to the present disclosure;

FIG. 8 is a schematic diagram of the multi-mode balun shown in FIG. 7 wherein the layers are stacked to each other;

FIG. 9A is a plotted graph showing an output power for a 2 dB compression (Pout_P2dB) with respect to a frequency range swept from 670 to 900 MHz of the 5G mode of the output matching network shown in FIG. 4 compared to a 5G baseline.

FIG. 9B is a plotted graph showing a maximum power added efficiency (max PAE) and a power added efficiency for a 2 dB compression (PAE_P2dB) with respect to a frequency range swept from 670 to 900 MHz of the 5G mode of the output matching network shown in FIG. 4 compared to a 5G baseline.

FIG. 10A is a plotted graph showing an insertional loss of the 2G mode (TXIL_2G) of the output matching network shown in FIG. 4, with respect to a frequency range swept from 824 MHz to 915 MHz, compared to a 2G baseline.

FIG. 10B is a plotted graph showing a real part of the collector impedance of the 2G mode (RpCOL_2G) of the output matching network shown in FIG. 4, with respect to a frequency range swept from 824 MHz to 915 MHz, compared to a 2G baseline.

FIG. 11A is a plotted graph showing a saturated power of the 2G mode (Psat) of the output matching network shown in FIG. 4, with respect to a frequency range swept from 824 MHz to 915 MHz, compared to a 2G baseline.

FIG. 11B is a plotted graph showing a maximum power added efficiency (max PAE) and a power added efficiency for a 2dB compression (PAE_P2dB) of the output matching network shown in FIG. 4, with respect to a frequency range swept from 824 MHz to 915 MHz, compared to a 2G baseline.

### DETAILED DESCRIPTION

Aspects and embodiments described herein are directed to a radio frequency front-end module that is capable of operating in both 2G-mode and 5G-mode communications and which covers a wide range of frequency bands and a wide range of power levels within 2G and 5G communications.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

The present disclosure relates to a radio frequency front-end module, or a mobile device, or a method for processing a radio frequency signal, or a radio frequency circuit for wireless communication.

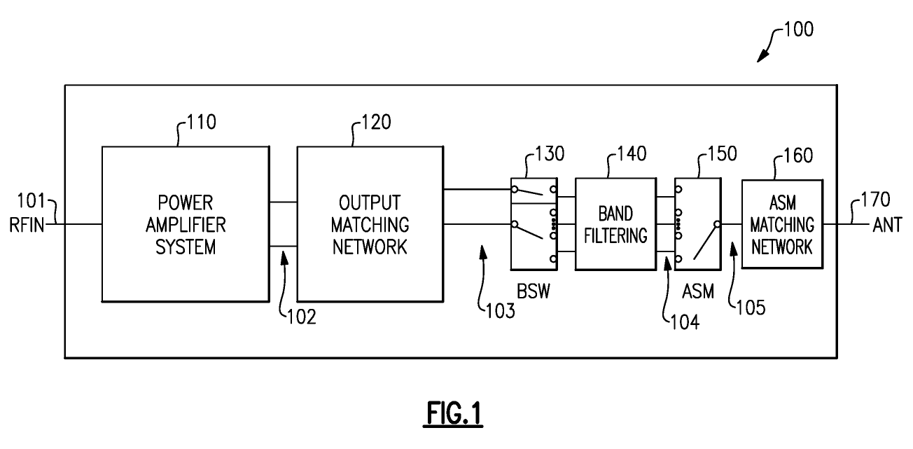

FIG. 1 is a schematic diagram of a radio frequency (RF) front-end module 100 according to one embodiment. The RF front-end module can be used in any RF communication system. Examples of RF communication systems include, but are not limited to, mobile phones, tablets, base stations, network access points, customer-premises equipment (CPE), laptops, and wearable electronics.

The RF front-end module 100 is implemented as a multi-chip module (MCM), and includes a module substrate, a compound semiconductor die attached to the module substrate, and a silicon switch die attached to the module substrate. In some embodiments, the compound semiconductor die is a heterojunction bipolar transistor (HBT) die, such as a GaAs or GaN die. In some embodiments, the silicon switch die is a silicon-on-insulator or SOI die.

As shown in FIG. 1, the RF front-end module 100 comprises a power amplifier system 110, an output matching network 120, a double-pole band switch (BSW) 130, a band filtering path 140, an antenna switch module (ASM) 150, an ASM matching network 160 and an antenna terminal (ANT) 170. A radio-frequency input signal (RFIN) 101 is input to the RF front-end module 100, processed by the power amplifier system 110 and the output matching network 120, and sent out through the ANT 170.

The power amplifier system 110 is configured to include one or more power amplifiers for providing amplification to the input signal RFIN. The power amplifier system 110 then provides one or more amplified RF signals 102 to the output matching network 120, which can provide matching (and in some implementations, combining and/or other functions) to generate an RF output signal 103 to the double-pole BSW 130.

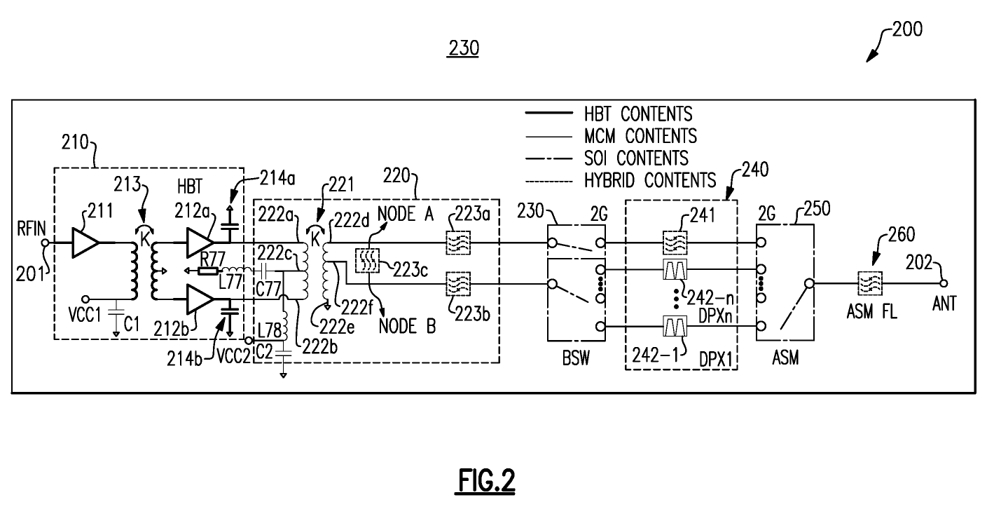

The output matching network 120 includes a multi-mode transformer balun (which is also referred to as multi-mode balun in this description) that is configured to tune the RF input signal to two different output modes. In some embodiments, the multi-mode balun is configured to operate in 2G and 5G modes. In some embodiments, the output matching network 120 can be operable in a 2G mode with frequency bands GSM850/900 and in a 5G mode with frequency bands B71, B12, B28, B13, B14, B26, B20 and B8. A more detailed description of the multi-mode balun is presented in FIG. 2.

The double-pole BSW 130 acts to route the relevant frequency components (e.g., for 2G and 5G) of the broadband RF signal to respective frequency specific paths to be further processed in the RF front-end module 100. The double-pole BSW 130 comprises at least two units of switches in parallel, including one switch for routing the 2G frequencies (e.g., 824 MHz to 849 MHz, 880 MHz to 915 MHz) and one switch for routing the 5G frequencies. The RF output signal 103 is therefore routed by the double-pole BSW 130 and output to the band filtering system 140. Each frequency path of the band filtering system 140 has respective band pass filters tuned to pass relevant in-band frequencies 104 of the respective path and to generate a filtered RF output signal 105 from the band filtering system 140. Such a type of double-pole switch is used with a switch for each band without inducing any additional switch losses as compared to any single-pole multiple throw switch.

Thereafter, the filtered RF output signal 105 is provided to the ASM 150. The ASM 150 routes the filtered RF output signal 105 to the ASM matching network 160 and then to the ANT 170 (which connects to an antenna) by way of the ASM output matching network 160.

For clarity of the figure, the MCM substrate, HBT die, and SOI die are not explicitly shown, but rather the correspondence of the depicted components to the MCM substrate, HBT die, and SOI die are indicated by line patterns in FIGS. 2 to 6 and will be discussed below.

FIG. 2 shows a schematic circuit diagram of the RF front-end module 200 according to one embodiment of the present invention.

The RF front-end module 200 includes a power amplifier system 210 for amplifying an RF input signal RFIN 201. The power amplifier system 210 is formed on the compound semiconductor die (e.g. HBT die). The RF front-end module 200 also includes an output matching network 220 formed directly on the MCM substrate, a double-pole band switch (BSW) 230 formed on the SOI die, a band filtering circuitry 240 wherein some of the components are formed on the MCM substrate and some other components are formed on the HBT die, an antenna switch module 250 formed on the SOI die, and an antenna switch module (ASM) output matching network 260 including an ASM filter. The RFIN input signal 201 is processed, routed, and eventually output by the RF front-end module 200, through an antenna terminal (ANT) 202 which connects to an antenna for transmission the processed signal to any corresponding RF device. However, the layout of each of the above components can be flexibly designed (e.g. depending on the desired quality factor).

In detail, the power amplifier system 210 includes an input transformer 213 having a primary winding and a secondary winding. The primary winding includes a first input power amplifier 211, and the secondary winding includes a first output power amplifier 212a and a second output power amplifier 212b. The power amplifier system 210 further includes a first capacitor 214a (formed on the HBT die) and a second capacitor 214b (formed on the HBT die) coupled to the first output power amplifier 212a and the second output power amplifier 212b, respectively. The first output power amplifier 212a is configured to conduct during the positive half-cycle, and the second output power amplifier 212b is configured to conduct during the negative half-cycle.

The output matching network 220 is coupled to the HBT die and includes a multi-mode transformer balun 221 formed on the MCM substrate. The multi-mode balun 221 includes an input side and an output side. The input side of the multi-mode balun 221 includes a primary winding having a first input terminal 222a, a second input terminal 222b and a center input tap 222c. The first input terminal 222a is coupled to an output of the first output power amplifier 212a. The second input terminal 222b is coupled to an output of the second output power amplifier 212b.

The input side of the multi-mode balun 221 also includes an input side choke inductor L78 (connected between a power supply voltage node of VCC2 and the center tap 222c of the input side of the multi-mode balun 221), an input side decoupling capacitor C2 (connected between the power supply voltage node VCC2 and ground), an input side termination network including a capacitor C77 and an inductor L77. The capacitor C77 and the inductor L77 are in series connection and are both formed on the MCM substrate. The input side termination network further includes a resistor R77 formed on the HBT die and is in series with the capacitor C77 and the inductor L77.

The multi-mode balun 221 is configured to receive the RFIN input signal at the input side and output one or more transmit RF signals from the output side which is tuned to different power levels through the multi-mode balun 221 (e.g., through different turns of coil of the secondary winding). The output side of the multi-mode balun 221 includes a secondary winding having a first output terminal 222d, a second output terminal 222e and an output tap 222f. The output side of the multi-mode balun 221 is coupled to a plurality of band filters 223. A first band filter 223a is coupled between the first output terminal 222d of the multi-mode balun 221 and a switch port (e.g., for 2G communication) of the band switch (BSW) 230. A second band filter 223b is coupled between the output tap 222f of the multi-mode balun 221 and a switch port (e.g., for 5G communication) of the BSW 230. A third band filter 223c is coupled between a node A and a node B. The node A is a node between the first output terminal 222d of the multi-mode balun 221 and the first band filter 223a and the node B is a node between the output tap 222f of the multi-mode balun 221 and the second band filter 223b. The second output terminal 222e is grounded.

In this way, as shown in FIG. 2, the band filters 223a, 223b, and 223c form two different frequency paths to respectively pass the relevant in-band frequencies of the respective paths, for the 2G output mode and the 5G output mode.

The double-pole BSW 230 includes two units wherein one of the units is configured to route the RF signal output from the output matching network 220 to a frequency path for 2G bands and the other one of the units is configured to route the RF signal output from the output matching network 220 to a plurality of ports and to a plurality of duplexers connected to the plurality of ports for frequency paths for 5G bands. The plurality of duplexers allow bi-directional communication over a single path. They isolate the receiver from the transmitter while permitting them to share a common antenna. The receive paths from the duplexers are not shown for conciseness.

In detail, as shown in FIG. 2, each unit of the double-pole BSW 230 is configured to branch out one or more ports connected to the band filtering system 240. The 2G unit of the BSW 230 is coupled to a band filter 241 of the band filtering system 240 through a port, and the 5G unit of the double-pole BSW 230 is coupled to a plurality of duplexer 242 (denoted as duplexers 242-1 to 242-n) through a plurality of respective ports.

The band filter 241 and the plurality of duplexers 242 are configured to each connect to a corresponding port of the ASM 250, wherein the ASM 250 includes a switch that is switchable among different ports of the ASM 250. The ASM 250 is then connected to the ASM filter of the ASM output matching network 260 and the processed signals are then transmitted through the antenna terminal (ANT) 202 and through an antenna connected to the ANT terminal 202.

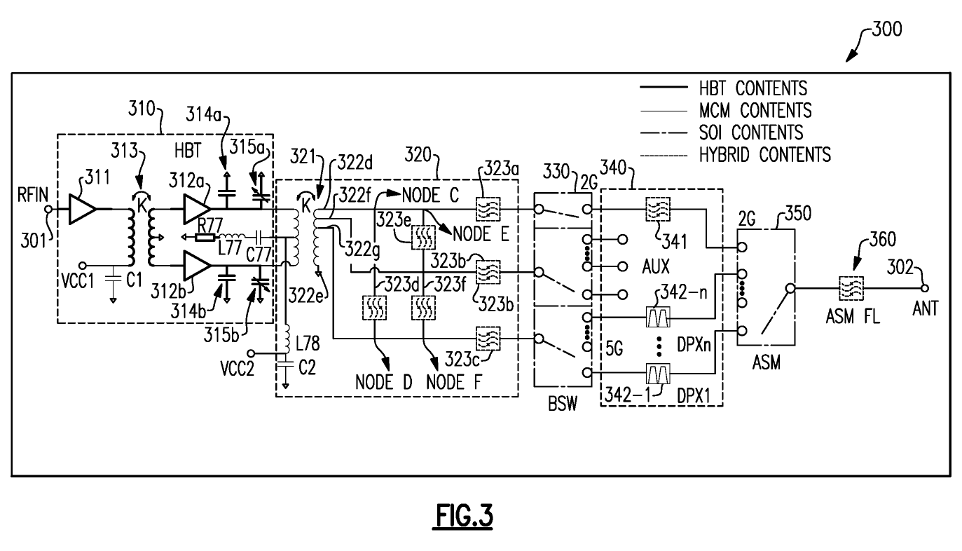

FIG. 3 shows a schematic circuit diagram of the RF front-end module 300 according to another embodiment of the present invention.

The RF front-end module 300 includes a power amplifier system 310 for amplifying an RF input signal RFIN 301 and formed on the compound semiconductor die (e.g. HBT die), an output matching network 320 formed on the MCM substrate, a triple-pole band switch (BSW) 330 formed on the SOI die, a band filtering circuitry 340, an antenna switch module 350 formed on the SOI die, and an antenna switch module (ASM) output matching network 360 including an ASM filter. The RFIN input signal 301 is processed and then output through an antenna terminal (ANT) 302 which connects to an antenna for transmission the processed signal to any corresponding RF device.

The compound semiconductor die, the SOI semiconductor die, the power amplifier output matching network, the band filters, and the ASM output matching network are each attached to the module substrate.

Similar to the power amplifier system 210 shown in FIG. 2, the power amplifier system 310 also includes a power amplifier core comprising a first input power amplifier 311, a first output power amplifier 312a, a second output power amplifier 312b, and an input transformer 313. Similar to the power amplifier system 210 shown in FIG. 2, the power amplifier system 310 also includes a first capacitor 314a (formed on the HBT die) and a second capacitor 314b (formed on the HBT die) coupled to an output of the first output power amplifier 312a and the second output power amplifier 312b, respectively.

The output matching network 320 is coupled to the HBT die and includes a multi-mode balun 321 formed on the MCM substrate. The multi-mode balun 321 includes an input side and an output side. Similar to FIG. 2, the input side of the multi-mode balun 321 also includes a primary winding including a first input terminal coupled to the output of the first output power amplifier 312a , a second input terminal coupled to the output of the second output power amplifier 312b, and a center input tap coupled to an input side choke inductor L78, an input side decoupling capacitor C2 (connected between the power supply voltage node VCC2 and ground), an input side termination network including a capacitor C77, an inductor L77 and a resistor R77 in series connection.

Different to the embodiment shown in FIG. 2, the power amplifier system 310 further includes a first switchable (i.e., variable) capacitor 315a and a second switchable (i.e., variable) capacitor 315b which are configured to provide load line adjustment to the power amplifier core to thereby provide bandwidth adjustment. The first switchable capacitor 315a is connected between the output of the first output power amplifier 312a and the first input terminal of the multi-mode balun 321. The first switchable capacitor 315a is in parallel to the first capacitor 314a. The second switchable capacitor 315b is connected between the output of the second output power amplifier 312b and the second input terminal of the multi-mode balun 321, and is in parallel to the second capacitor 314b.

The output side of the multi-mode balun 321 includes a secondary winding having a first output terminal 322d, a second output terminal 322e, a first output tap 322f, and a second output tap 322g. The output side of the multi-mode balun 321 is coupled to a plurality of band filters 323. A first band filter 323a is coupled between the first output terminal 322d of the multi-mode balun 321 and the band switch (BSW) 330. A second band filter 323b is coupled between the first output tap 322f of the multi-mode balun 321 and the BSW 330. A third band filter 323c is coupled between the second output tap 322g and a switch port of the BSW 330.

A fourth band filter 323d is coupled between a node C and a node D. The node C is a node between the first output terminal 322d of the multi-mode balun 321 and the first band filter 323a and the node D is a node between the second output tap 322g of the multi-mode balun 321 and the third band filter 323c. A fifth band filter 323e and a sixth band filter 323f are in series connection and are coupled between a node E and a node F. The node E is a node between the node C and the first band filter 323a, and the node F is a node between the node D and the third band filter 323c. The second output terminal 322e is grounded.

In this way, as shown in FIG. 3, the band filters 323a to 323f form three different frequency paths to respectively pass the relevant in-band frequencies of the respective paths, for the 2G output mode and the 5G output mode.

The triple-pole BSW 330 includes three units of switches namely a 2G switch unit, a 5G switch unit and an additional AUX switch unit. In some embodiments, the AUX switch unit is for a 5G path but may have power levels different from the path of the other 5G switch unit. The AUX switch unit can be hooked with other circuitry such as duplexers to provide more freedom of uses, other than only the 2G and 5G paths. The 2G switch is configured to route the RF signal output from the output matching network 320 to a frequency path for 2G bands. The port of the 2G switch is coupled to a band filter 341 of the band filtering system 340. The 5G switch is configured to route the RF signal output from the output matching network 320 to a plurality of ports and to a plurality of duplexers connected to the plurality of ports for frequency paths for 5G bands. Each of the port of the 5G switch of the BSW 330 is respectively coupled to a duplexer 342 (denoted as duplexers 342-1 to 342-n). The plurality of duplexers allow bi-directional communication over a single path. They isolate the receiver from the transmitter while permitting them to share a common antenna.

The band filter 341 and the plurality of duplexers 342 are configured to each connect to a corresponding port of the ASM 350, wherein the ASM 350 includes a switch that is switchable among different ports of the ASM 350. The ASM 350 is then connected to the ASM filter of the ASM output matching network 360 and the processed signals are then transmitted through the antenna terminal (ANT) 302 and through an antenna connected to the ANT terminal 302.

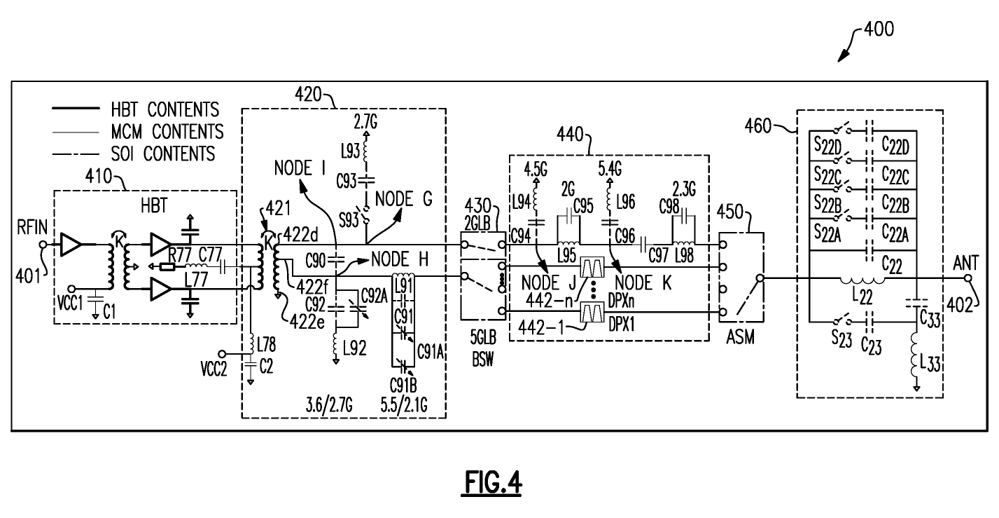

FIG. 4 shows a schematic circuit diagram of the RF front-end module 400 according to another embodiment of the present disclosure.

The RF front-end module 400 includes a power amplifier system 410 for amplifying a RF input signal RFIN 401 and formed on the compound semiconductor die (e.g. HBT die), an output matching network 420 formed on the MCM substrate, a band switch (BSW) 430 formed on the SOI die, a band filtering circuitry 440, an antenna switch module 450 formed on the SOI die, and an antenna switch module (ASM) output matching network 460. The RFIN input signal 401 is processed and then output through an antenna terminal (ANT) 402 which connects to an antenna for transmission the processed signal to any corresponding RF device.

The power amplifier system 410 of the RF front-end module 400 includes the same set up for the power amplifier system 210 as described in FIG. 2. The output matching network 420 of the RF front-end module 400 includes a multi-mode balun 421 having an input side and an output side. The input side of the multi-mode balun 421 has the same set up for the input side of the multi-mode balun 221 described in FIG. 2.

Similar to FIG. 2, the output side of the multi-mode balun 421 also includes a first output terminal 422d, a second output terminal 422e and a tap 422f. However, different to the configuration of FIG. 2, first output terminal 422d is coupled to the band filtering circuitry 440 through the BSW 430.

FIG. 4 shows an implementation of the band filtering circuitry shown in FIG. 2 in which a set of capacitors and inductors are connected to provide the functions of band filtering as described in FIG. 2. In detail, the band filtering circuitry includes a switch S93, a capacitor C93 and an inductor L93 in series connection which are connected to the output side of the multi-mode balun 421 at a node G. The node G is a node between the first output terminal 422d and a port of the BSW 430. The capacitor C93 and the inductor L93 in series connection are configured to be resonant at certain frequencies.

An inductor L91, a capacitor C91, a switchable (i.e., variable) capacitor C91A and a switchable capacitor C91B are in parallel with each other, having a resonant frequency of 5.5 or 2.1 GHz, and coupled between the tap 422f and a port of the BSW 430. A capacitor C92 and an inductor L92 are in a series connection. The capacitor C92 and a switchable (i.e., variable) capacitor C92A are in a parallel connection. The capacitor C92, inductor L92 and the switchable capacitor C92A are coupled to a node H, having a resonant frequency of 3.6 or 2.7 GHz. The node H is between the tap 422f and the inductor L91. A capacitor C90 is connected between the node I and the node H. The second output terminal 422e is grounded. The switchable capacitors can change the capacitance values for fine tuning of the resonant frequencies to meet different harmonic rejections requirements for the RF front-end module.

In this way, as shown in FIG. 4, the band filtering circuitry 420 forms two different frequency paths to respectively pass the relevant in-band frequencies of the respective paths for the 2G output mode and the 5G output mode. The capacitor C90 serves as an isolation between the two frequency paths as it forms a tank with the secondary winding of the output side of the multi-mode balun. The switch S93 should be off when operating in the 5G output mode.

The BSW 430 includes two switches, namely a 2G switch and a 5G switch. The 2G switch is configured to route the RF signal output from the output matching network 420 to a frequency path for 2G bands. Instead of coupling to a band filter, the port of the 2G switch of BSW 430 is coupled to a circuit consisting of a number of electrical components. The circuit includes an inductor L95, a capacitor C97 and an inductor L98 which are in series connection. The circuit also includes a capacitor C95 in parallel with the inductor L95 having a resonant frequency of 2 GHz, and a capacitor C98 in parallel with the inductor L98 having a resonant frequency of 2.3 GHz. A capacitor C94 is in series with an inductor L94 and they are connected to a node J of the band filtering circuit 440, having a resonant frequency of 4.5 GHz. The node J is a node between a port of the 2G switch and the inductor L95. Similarly, a capacitor C96 is in series with an inductor L96 having a resonant frequency of 5.4 GHz and they are connected to a node K of the band filtering circuit 440. The node K is a node between the port of the 2G switch and the inductor L98. In some embodiments, the total capacitance of the capacitors C90, C93, C94, C96, and C98 is lower than 7 pF.

The capacitors C94, C96 and C98 are all formed on the SOI die. The inductors L94, L95, L96 and L98 are all formed on the MCM substrate. The capacitors C95 and C97 are both formed on the MCM substrate.

The 5G switch is configured to route the RF signal output from the output matching network 420 to a plurality of ports and to a plurality of duplexers connected to the plurality of ports for frequency paths for 5G bands. Each of the port of the 5G switch of the BSW 430 is respectively coupled to a duplexer 442 (denoted as duplexers 442-1 to 442-n).

The output of the circuit consisting of the capacitors C94, C95, C96, C97 and C98 and the inductors L94, L95, L96 and L98, and the plurality of duplexers 442 are configured to each connect to a corresponding port of the ASM 450, wherein the ASM 450 includes a switch that is switchable among different ports of the ASM 450. The ASM 450 is then connected to the ASM filter of the ASM output matching network 460 and the processed signals are then transmitted through the antenna terminal (ANT) 402 and through an antenna connected to the ANT terminal 402.

The ASM output matching network 460 includes a circuit instead of a band filter. The ASM output matching network 460 includes a plurality of switches S_{22A} to S_{22D} and a plurality of capacitors C_{22A} to C_{22D}. Each of the switches is in series with a respective capacitor (e.g., the switch S_{22A} is in series with the capacitor C_{22A}) for a plurality of groups of switches in series with capacitors. The groups are in parallel connection to each other. The ASM output matching network 460 also includes a capacitor C22 in parallel to the groups of switches and capacitors. The ASM output matching network 460 also includes an inductor L22 in parallel to the groups of switches and capacitors. The ASM output matching network 460 also includes a switch S23 and a capacitor C23 in series with each other and in parallel with the groups of switches and capacitors. A capacitor C33 is connected between the ANT 402 terminal and the capacitor C23, and an inductor L33 is connected between the capacitor C33 and ground.

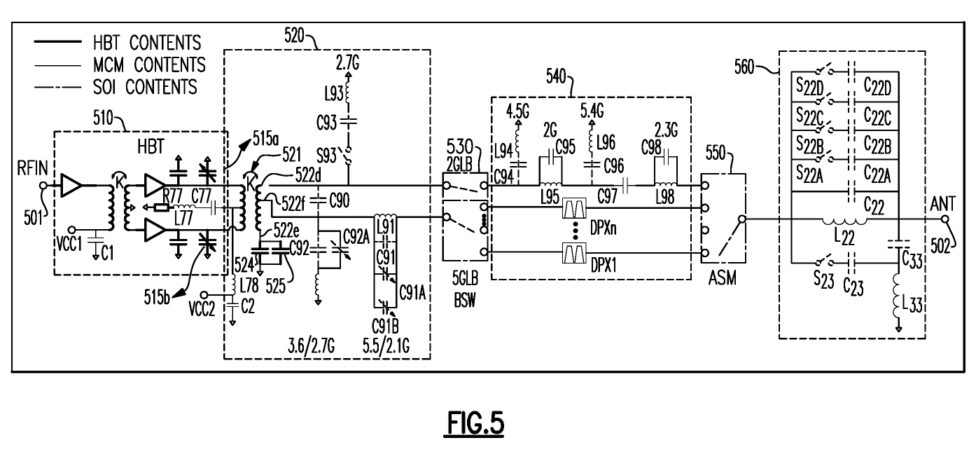

FIG. 5 shows a schematic circuit diagram of the RF front-end module 500 according to another embodiment of the present disclosure.

The RF front-end module 500 includes a power amplifier system 510 for amplifying an RF input signal RFIN 501 and formed on the compound semiconductor die (e.g. HBT die), an output matching network 520 formed on the MCM substrate, a band switch (BSW) 530 formed on the SOI die, a band filtering circuitry 540, an antenna switch module 550 formed on the SOI die, and an antenna switch module (ASM) output matching network 560. The RFIN input signal 501 is processed and then output through an antenna terminal (ANT) 502 which connects to an antenna for transmission of the processed signal to any corresponding RF device.

The power amplifier system 510 of the RF front-end module 500 includes the same set up for the power amplifier system 310 as described in FIG. 3. The power amplifier system 510 includes a first switchable (i.e., variable) capacitor 515a and a second switchable (i.e., variable) capacitor 515b, and they are coupled to the output power amplifiers in the same manner as described in FIG. 3.

The output matching network 520 of the RF front-end module 500 includes a multi-mode balun 521 having an input side and an output side. The input side and the output side of the multi-mode balun 521 include the same set up for the input side and outside of the multi-mode balun 421 described in FIG. 4.

In addition to the output matching network 420 of the RF front-end module 400, the output matching network 520 of the RF front-end module 500 further includes two termination capacitors 524 and 525 in parallel connection and connected between a second output terminal 522e of the multi-mode balun 521 and ground.

The configurations of the BSW 530, the band filtering circuitry 540, the ASM 550, and the ASM output matching network 560 are the same as described in FIG. 4.

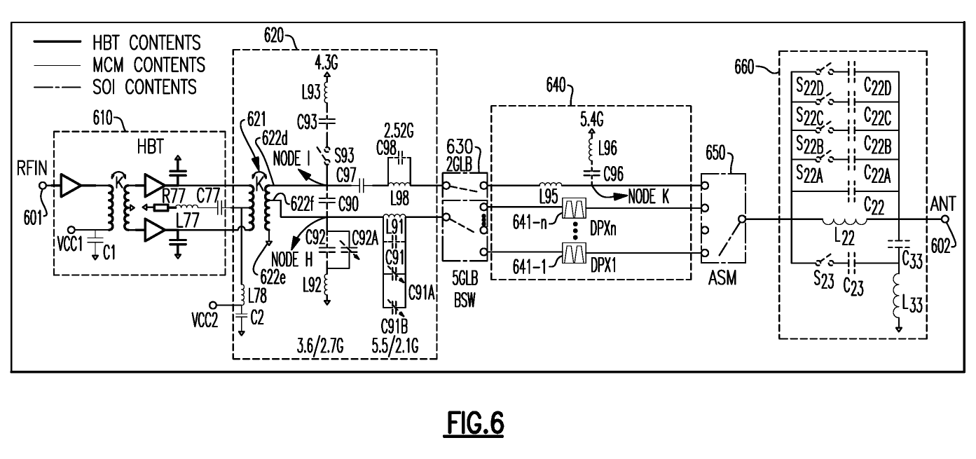

FIG. 6 shows a schematic circuit diagram of the RF front-end module 600 according to another embodiment of the present disclosure.

The RF front-end module 600 includes a power amplifier system 610 for amplifying an RF input signal RFIN 601 and formed on the compound semiconductor die (e.g., HBT die), an output matching network 620 formed on the MCM substrate, a band switch (BSW) 630 formed on the SOI die, a band filtering circuitry 640, an antenna switch module 650 formed on the SOI die, and an antenna switch module (ASM) output matching network 660. The RFIN input signal 601 is processed and then output through an antenna terminal (ANT) 602 which connects to an antenna for transmission of the processed signal to any corresponding RF device.

In this embodiment, a number of modifications are made based on the RF front-end module 400 as shown in FIG. 4. The power amplifier system 610, BSW 630, ASM 650 and ASM output matching network 660 are unchanged as compared to the power amplifier system 410, BSW 430, ASM 450 and ASM output matching network 460 of the RF front-end module 400.

The output matching network 620 and the band filtering circuity 640 are modified in order to simplify the 2G frequency path. Similar to FIG. 4, the output matching network 620 includes a multi-mode balun 621. The multi-mode balun 621 has an input side including a primary winding and an output side including a secondary winding. The secondary winding of the output side includes a first output terminal 622d, a second output terminal 622e, and a third output terminal 622f. The first output terminal 622d is coupled to a 2G switch of the BSW 630 and the 2G switch is coupled to a port of the ASM 650, to form a 2G frequency path for the RF output signal. The third output terminal 622f is coupled to a 5G switch of the BSW 630 and the 5G switch is coupled to a plurality of ports of the ASM 650, to form a 5G frequency path for the RF output signal.

In this embodiment, only the 2G frequency path is modified based on the embodiment shown in FIG. 4. In detail, the switch S93, the capacitor C93 and the inductor L93 are in series connection, having a resonant frequency of 4.3 GHz, and are connected to the output side of the multi-mode balun 621 at the node I. In addition, the capacitor C97 and the inductor L98 in parallel to the capacitor C98, which are in the band filtering circuitry 440, are moved to the frequency path coupled between the first output terminal 622d and the BSW 630.

The remaining configurations of the inductor L91, the capacitor C91, the switchable capacitor C91A, the switchable capacitor C91B, the capacitor C92, the inductor L92, the switchable capacitor C92A are not changed.

In the band filtering circuitry 640, the 2G path is simplified by removing the capacitor C94, the inductor L94 and the capacitor C95, as compared to the embodiment shown in FIG. 4.

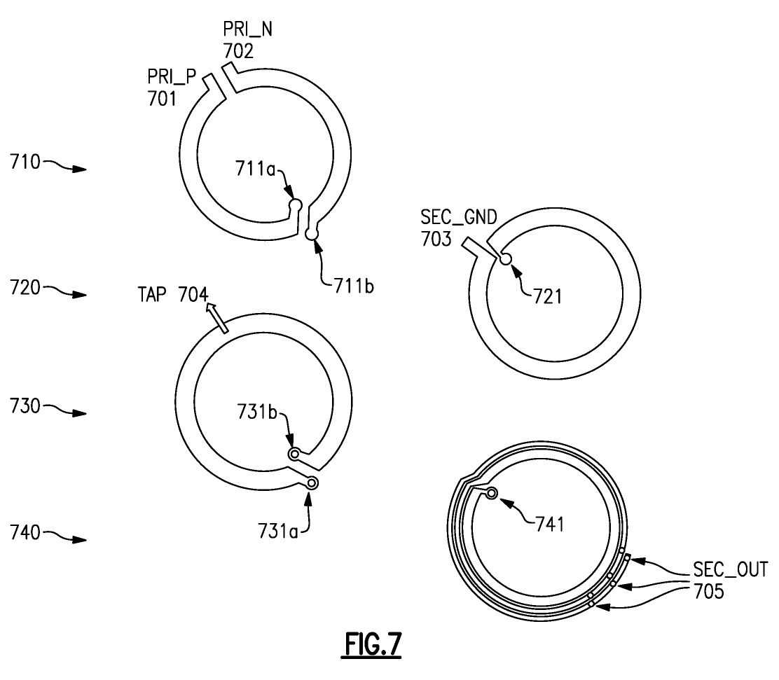

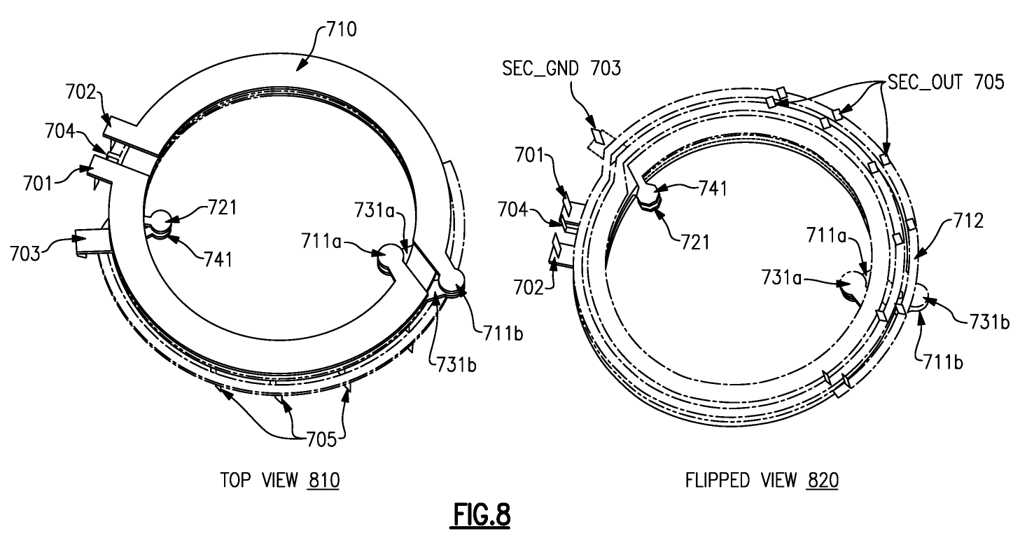

FIGS. 7 and 8 show schematic diagrams of a multi-mode balun used in any of the embodiments described above. FIG. 7 shows each layer of the multi-mode balun and FIG. 8 shows the assembled multi-mode balun and shows the connections between layers.

FIG. 7 shows four layers of the multi-mode balun, namely a top layer 710, a first middle layer 720, a second middle layer 730 and a bottom layer 740. The top layer 710 comprises a first input terminal 701, a second input terminal 702, a first connection point 711a and a second connection point 711b. The first middle layer 720 includes a first output terminal 703 and first connection point 721. The second middle layer 730 includes a tap 704, a first connection point 731a and a second connection point 731b. The bottom layer 740 includes a plurality of output taps 705 and a first connection point 741.

FIG. 8 shows a top view 810 and a flipped view 820 of the multi-mode balun in which the four layers 710, 720, 730 and 740 shown in FIG. 7 are assembled in a stack. The top layer 710 is connected to the second middle layer 730 through the connection points. The bottom layer 740 is connected to the first middle layer 720 through the connection points.

As shown by the top view 810, the first connection point 711a and the second connection point 711b of the top layer 710 are respectively connected to the first connection point 731a and the second connection point 731b of the second middle layer 730. The connections can also be seen in the flipped view 820. The first connection point 721 of the first middle layer 720 is connected to the first connection point 741 of the bottom layer 740. The connections can also be seen in the flipped view 820. Further, the flipped view 820 shows the plurality of taps 705 of the bottom layer 740 which act as a plurality of output ports to be connected to a subsequent circuitry (e.g., for band filters).

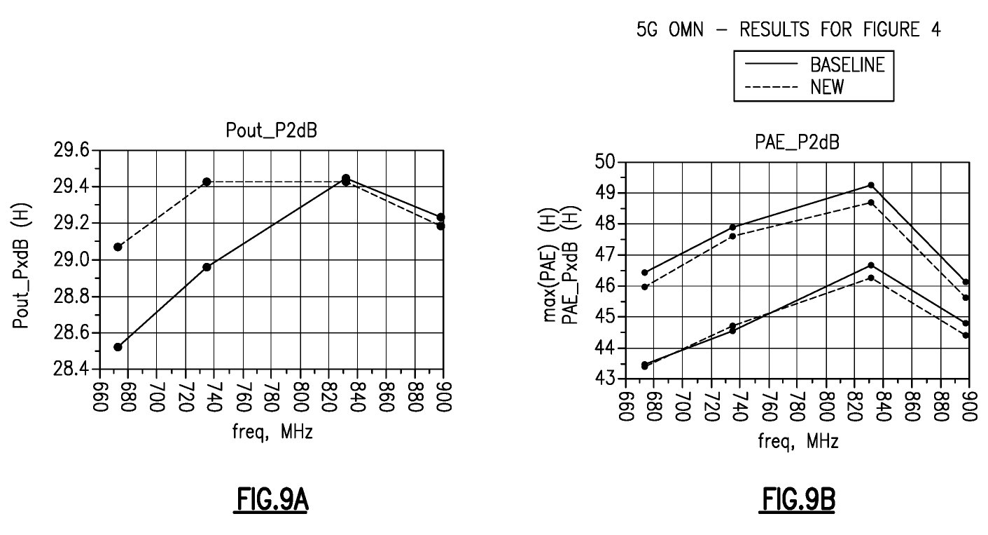

FIGS. 9 to 11 depict the 2G and 5G performance of the output matching network, using a multi-mode balun, shown in FIG. 4 compared to a baseline in which a known single-mode balun is used.

FIG. 9A shows an output power for a 2 dB compression (Pout_P2dB) with respect to a frequency range swept from 670 to 900 MHz of the 5G mode of the output matching network shown in FIG. 4 compared to a 5G baseline. FIG. 9B shows a maximum power added efficiency (max PAE) and a power added efficiency for a 2 dB compression (PAE_P2dB) with respect to a frequency range swept from 670 to 900 MHz of the 5G mode of the output matching network shown in FIG. 4 compared to a 5G baseline. As can be seen in FIGS. 9A and 9B, by using the multi-mode balun according to the present disclosure, the 5G performance is largely maintained as compared to the 5G performance of the known single-mode balun.

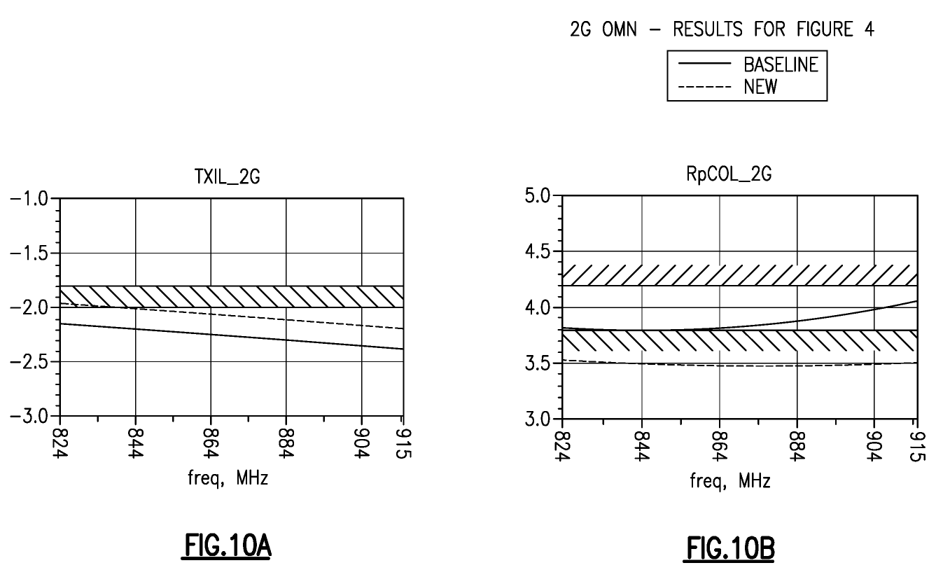

FIG. 10A shows an insertion loss of the 2G mode (TXIL_2G) of the output matching network shown in FIG. 4, with respect to a frequency range swept from 824 MHz to 915 MHz, compared to a 2G baseline. FIG. 10B shows a real part of the collector impedance of the 2G mode (RpCOL_2G) of the output matching network shown in FIG. 4, with respect to a frequency range swept from 824 MHz to 915 MHz, compared to a 2G baseline. As can be seen in FIGS. 10A and 10B, by using the multi-mode balun according to the present disclosure, the 2G performance is also largely maintained as compared to the 2G performance of the known single-mode balun.

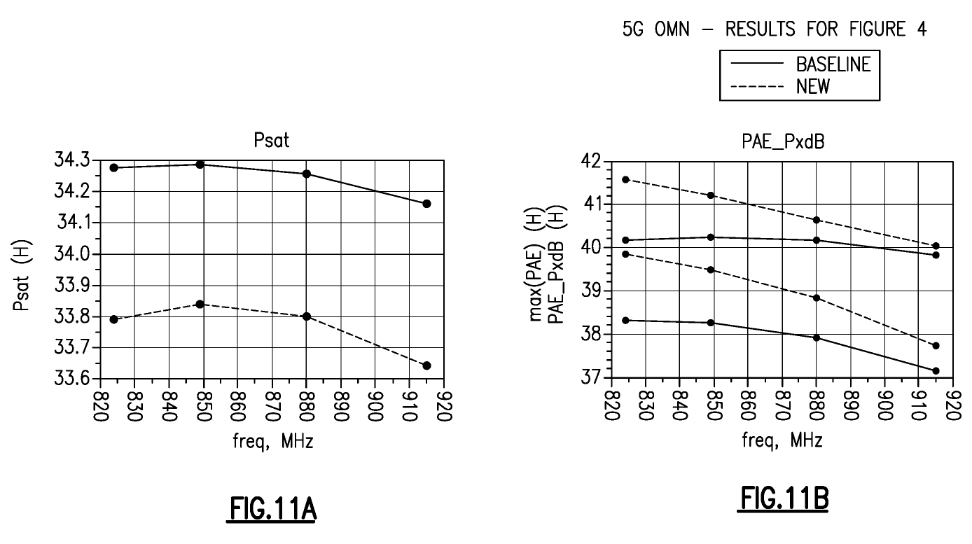

FIG. 11A shows a saturated power of the 2G mode (Psat) of the output matching network shown in FIG. 4, with respect to a frequency range swept from 824 MHz to 915 MHz, compared to a 2G baseline. FIG. 11B shows a maximum power added efficiency (max PAE) and a power added efficiency for a 2dB compression (PAE_P2dB) of the output matching network shown in FIG. 4, with respect to a frequency range swept from 824 MHz to 915 MHz, compared to a 2G baseline. As can be seen in FIG. 11A, the 2G power is improved by 0.5dB compared to the known single-mode balun. As can be seen in FIG. 11B, the PAE is also improved by 1% to 2% compared to the known single-mode balun. In some embodiments, the power can be further boosted if needed by adjusting the balun’s parameters.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. A radio frequency front-end module comprising:
a module substrate;
a semiconductor die attached to the module substrate, the semiconductor die including a power amplifier system formed on the semiconductor die and configured to amplify a radio frequency signal provided as an input to the radio frequency front-end module; and
an output matching network configured to tune the radio frequency signal to at least a first output mode having a first output power level in a first output frequency range and a second output mode having a second output power level in a second output frequency range,
the output matching network including a multi-mode balun having an input side coupled to the power amplifier system and an output side having a plurality of output terminals directing the radio frequency signal from the power amplifier system to at least the first and the second output modes.

2. The radio frequency front-end module of claim 1 wherein the input side of the multi-mode balun has a primary winding having a positive input terminal, a negative input terminal, and a center tap directed to ground.

3. The radio frequency front-end module of claim 1 wherein the output side of the multi-mode balun has a secondary winding having a first output terminal directed to the first output mode of the multi-mode balun, a second output terminal directed to ground and at least one output tap directed to the second output mode of the multi-mode balun.

4. The radio frequency front-end module of claim 2 wherein the power amplifier system further comprises a first input power amplifier, a first output power amplifier, a second output power amplifier and an input transformer.

5. The radio frequency front-end module of claim 4 wherein an output of the first output power amplifier is coupled to the positive input terminal, and an output of the second output power amplifier is coupled to the negative input terminal.

6. The radio frequency front-end module of claim 5 wherein the power amplifier system further comprises a first capacitor coupled at the output of the first output power amplifier, and a second capacitor coupled at the output of the second output power amplifier.

7. The radio frequency front-end module of claim 6 wherein the power amplifier system further comprises a third variable capacitor coupled at the output of the first output power amplifier, and a fourth variable capacitor coupled at the output of the second output power amplifier.

8. The radio frequency front-end module of claim 1 wherein the multi-mode balun is in a multi-layer structure including at least a top layer having a positive input terminal and a negative input terminal, a first middle layer having a first output terminal, a second middle layer having a center input tap, and a bottom layer having a plurality of output taps.

9. The radio frequency front-end module of claim 8 wherein the top layer is connected to the second middle layer forming the input side of the multi-mode balun and the bottom layer is connected to the first middle layer forming the output side of the multi-mode balun.

10. The radio frequency front-end module of claim 9 wherein the bottom layer is connected to the first middle layer forming the output side of the multi-mode balun.

11. The radio frequency front-end module of claim 1 wherein the first output frequency range is within a Second Generation communication frequency range and the second output frequency range is within a Fifth Generation communication frequency range.

12. The radio frequency front-end module of claim 1 wherein the multi-mode balun is configured to provide a third output mode having a third output power level in a third output frequency range.

13. The radio frequency front-end module of claim 12 wherein the third output frequency range is within a Fifth Generation communication frequency range.

14. The radio frequency front-end module of claim 1 wherein the output matching network further comprises a band filtering circuitry formed on the module substrate and coupled to the multi-mode balun, the band filtering circuitry including a plurality of band filters.

15. The radio frequency front-end module of claim 1 further comprising a band switch formed on a silicon switch die attached to the module substrate and configured to switch between the first output mode and the second output mode.

16. A mobile device comprising a transceiver configured to generate a radio frequency input signal, and a radio frequency front-end module, the radio frequency front-end module including:
a module substrate;
a semiconductor die attached to the module substrate, the semiconductor die having a power amplifier system formed on the semiconductor die and configured to amplify a radio frequency signal provided as an input to the radio frequency front-end module; and
an output matching network configured to tune the radio frequency signal to at least a first output mode having a first output power level in a first output frequency range and a second output mode having a second output power level in a second output frequency range,
the output matching network having a multi-mode balun having an input side coupled to the power amplifier system and an output side having a plurality of output terminals directing the radio frequency signal from the power amplifier system to at least the first and the second output modes.

17. The mobile device of claim 16 wherein the multi-mode balun is in a multi-layer structure including at least a top layer, a first middle layer, a second middle layer, and a bottom layer.

18. A method for processing a radio frequency signal, the method comprising:
inputting a radio frequency to a radio frequency front-end module formed on a module substrate;
amplifying the radio frequency signal using a power amplifier system formed on a semiconductor die attached to the module substrate to produce an amplified radio frequency signal;
tuning the amplified radio frequency signal, using an output matching network, to at least a first output mode having a first output power level in a first output frequency range and a second output mode having a second output power level in a second output frequency range, including forming at least the first and the second output modes using a multi-mode balun, the multi-mode balun having an input side coupled to the power amplifier system and an output side having a plurality of output terminals directing the radio frequency signal from the power amplifier system to form at least the first and the second output modes.

19. The method of claim 18 wherein the multi-mode balun is in a multi-layer structure including at least a top layer, a first middle layer, a second middle layer, and a bottom layer.

20. The method of claim 18 wherein the first output frequency range is within a Second Generation communication frequency range and the second output frequency range is within a Fifth Generation communication frequency range.
